(19) United States
(12) Patent Application Publication
(10) Pub. No.: US 2011/0310229 A1
(43) Pub. Date: Dec. 22, 2011

(54) PROFILE MEASURING DEVICE, PROFILE MEASURING METHOD, AND METHOD OF MANUFACTURING SEMICONDUCTOR PACKAGE

(75) Inventor: Keisuke UEDA, Nagano-shi (JP)

(73) Assignee: Shinko Electric Industries Co., Ltd., Nagano-shi (JP)

(21) Appl. No.: 13/163,943

(22) Filed: Jun. 20, 2011

(30) Foreign Application Priority Data
Jun. 21, 2010 (JP) 2010-140700

(51) Int. Cl. H04N 7/18; H01L 21/00; H04N 13/02

(52) U.S. Cl. 348/46; 348/87; 29/25.01; 348/E07.085

(57) ABSTRACT

There is provided a profile measuring device. The profile measuring device includes: a projector which projects a certain pattern on an object to be measured using incoherent light having a plurality of wavelength components; a first imaging device which captures a first image of the object on which the certain pattern is projected; a second imaging device which captures a second image of the object on which the certain pattern is projected; and a computing device which measures a profile of the object based on the first image and the second image.

### BACKGROUND

1. Technical Field

Embodiments described here relate to a profile measuring device, a profile measuring method and a method of manufacturing a semiconductor package.

2. Related Art

In a manufacturing process of semiconductor packages in each of which a semiconductor device (semiconductor chip) is mounted on a substrate or a wiring board, a board in a state that semiconductor packages have not yet been separated into individual products is handled as a large-size panel.

To measure a profile such as a warpage and deviations of such a panel, warpage measuring methods using data taken from several points are used, examples of which are a method in which distances from a base are measured using a ruler, vernier calipers, a thickness gauge with a panel placed on a horizontal plane and a method in which distances from a wall is measured by pressing a panel against the wall. However, none of these measuring methods are sufficiently accurate for quantitative evaluation.

Other methods for measuring a profile of such a panel are methods for using a contact measuring device or a non-contact measuring device. The method using a contact measuring device cannot measure the profile of a panel having a large warpage because of a limited measurement range. Among non-contact measuring device, CNC (computer numerical control) image measuring device are not suitable for flatness measurement of a large-size panel because of a structure that a base and a head incorporating a measurement lens have a slide portion. Furthermore, a long measurement time is necessary because measurement needs to be performed on several tens of points on a point-by-point basis.

On the other hand, the above-mentioned measuring method using a ruler or the like with a panel is placed on a horizontal plane is not suitable for, for example, use in a semiconductor package manufacturing process as part of a manufacturing line because a measurement takes too long time.

In contrast to the above profile measuring techniques, a 3D digital image correlation method is suitable for measurement of a profile such as a warpage and deviations of a panel because no slide portion exists and a profile is recognized based on an instantaneous still image. To measure the profile of a panel by this image correlation method, a random black-and-white pattern called a speckle pattern needs to be formed on the surface of an object to be measured (sample). And this pattern needs to have a size that is suitable for a field-of-view size of an imaging device (camera) for capturing an object to be measured and an image pixel size. This pattern is indispensable for image recognition and is formed by coating conventionally.

Japanese patent documents JP-A-8-14824 and JP-A-2003-262510 describe measuring a movement (variation) of an object to be measured using a laser speckle method. The laser speckle method performs a measurement by capturing a speckle pattern that is formed by interference between light beams that are reflected randomly from the surface of an object being illuminated with single-wavelength laser light (coherent light).

Laser light is high in directivity and monochromaticity, it is coherent, and it enables application of high-density energy. Measurement techniques using the laser speckle method as described in JP-A-8-14824 and JP-A-2003-262510 measure a movement of an object based on the fact that a laser speckle pattern which is an irregular luminance distribution that appears when the object is illuminated with laser light translates at a speed that is proportional to a speed of the object as the object moves.

For example, a board used for manufacture of semiconductor packages may be changed in profile (e.g., warped) in a manufacturing process. In such an event, its handleability lowers when it is transported. Positional deviations occur when via holes or grooves are formed through or in an insulating layer or wiring patterns are formed. Furthermore, trouble may occur in positioning when an electronic component (e.g., semiconductor chip or chip capacitor) is mounted. One factor that causes a warpage of a board is stress that is caused by differences between the thermal expansion coefficients of constituent members of each semiconductor package such as an insulating layer (e.g., thermosetting resin layer or photosensitive resin layer), wiring patterns (e.g., metal patterns), and a semiconductor chip (e.g., silicon chip).

If a board is changed in profile (e.g., warped), the production yield of semiconductor packages or the reliability of final products may lower. Therefore, recognizing the profile of a board of semiconductor packages during a manufacturing process, for example, in a state that wiring layers or wiring patterns have been formed and a state that an electronic component has been mounted is useful in increasing the production yield and the reliability of semiconductor packages.

However, where a profile of a board of semiconductor packages (object to be measured) is measured by an image correlation method in which a speckle pattern is coated, to control the size of a speckle pattern, it is necessary to learn the skill of spraying paint onto the surface of the board while adjusting the grain size. Even if such a coating skill is learned, it is difficult to coat similar speckle patterns on plural boards and perform evaluation under the same conditions.

Furthermore, since the surface of a board of semiconductor packages (object to be measured) is coated, a coated board is regarded as a defective one (damaged one) even if it has no warpage, displacements, or the like. That is, the profile measurement necessarily causes reduction of the production yield of semiconductor packages. Therefore, one may hesitate to use, for a flow survey in a manufacturing process, a product inspection, etc., the image correlation method in which a speckle pattern is coated though it is a technique capable of non-contact measurement.

Still further, where the laser speckle method is used for measurement of a profile of a board of semiconductor packages (object to be measured), depending on the wavelength of laser light (coherent light), there may occur an event that a profile of a board cannot be measured correctly because the laser light is reflected by part of the constituent members (e.g., metal pattern) of a semiconductor package and passes through the other constituent members (e.g., a thermosetting resin layer). In addition, depending on the illumination intensity, a photosensitive resin layer may sense or is deteriorated by laser light and a board may be damaged by laser light (physically).

### SUMMARY OF THE INVENTION

Exemplary embodiments of the present invention address the above disadvantages and other disadvantages not described above. However, the present invention is not required to overcome the disadvantages described above, and thus, an exemplary embodiment of the present invention may not overcome any disadvantages described above.

According to one or more illustrative aspects of the present invention, there is provided a profile measuring device. The device includes: a projector which projects a certain pattern on an object to be measured using incoherent light having a plurality of wavelength components; a first imaging device which captures a first image of the object on which the certain pattern is projected; a second imaging device which captures a second image of the object on which the certain pattern is projected; and a computing device which measures a profile of the object based on the first image and the second image.

According to one or more illustrative aspects of the present invention, there is provided a profile measuring method. The method includes: (a) projecting a certain pattern on an object to be measured using incoherent light having a plurality of wavelength components; (b) capturing a first image of the object on which the certain pattern is projected; (c) capturing a second image of the object on which the certain pattern is projected; and (d) measuring a profile of the object based on the first image and the second image.

According to one or more illustrative aspects of the present invention, there is provided a profile measuring method. The method includes: (a) projecting a certain pattern on an object to be measured using incoherent light having a plurality of wavelength components; (b) capturing a first image of the object on which the certain pattern is projected; (c) capturing a second image of the object on which the certain pattern is projected; and (d) measuring a profile of the object based on the first image and the second image.

According to one or more illustrative aspects of the present invention, there is provided a method of manufacturing a semiconductor package. The method includes: (a) providing a wiring board for the semiconductor package, comprising wiring layers and insulating layers; (b) projecting a certain pattern on the wiring board using incoherent light having a plurality of wavelength components; (c) capturing a first image of the wiring board on which the certain pattern is projected; (d) capturing a second image of the wiring board on which the certain pattern is projected; and (e) measuring a profile of the wiring board based on the first image and the second image.

According to one or more illustrative aspects of the present invention, there is provided a method of manufacturing a semiconductor package. The method includes: (a) providing a wiring board comprising wiring layers and insulating layers; (b) mounting an electronic component on the wiring board, thereby obtaining a semiconductor package comprising the electronic component and the wiring board; (c) projecting a certain pattern on the semiconductor package using incoherent light having a plurality of wavelength components; (d) capturing a first image of the semiconductor package on which the certain pattern is projected; (e) capturing a second image of the semiconductor package on which the certain pattern is projected; and (f) measuring a profile of the semiconductor package based on the first image and the second image.

Other aspects and advantages of the present invention will be apparent from the following description, the drawings and the claims.

### BRIEF DESCRIPTION OF THE DRAWINGS

FIG. 1 illustrates a general configuration of a profile measuring device according to an embodiment of the present invention;

FIG. 2 is a block diagram showing the configuration of the profile measuring device shown in FIG. 1;

FIG. 3 is a flowchart for description of the profile measuring method using the profile measuring device shown in FIG. 1;

FIG. 4 is a sectional view of a wiring board during a manufacturing process using the profile measuring device shown in FIG. 1;

FIG. 5 is a sectional view of a semiconductor package after the manufacturing process shown in FIG. 4; and

FIG. 6 is a plan view of a panel in which a plurality of wiring boards can be obtained.

### DETAILED DESCRIPTION OF EXEMPLARY EMBODIMENTS

An embodiment of the present invention will be hereinafter described in detail with reference to the drawings. In all the drawings for description of the embodiment, members having the same function are given the same reference symbol and may not be described repeatedly.

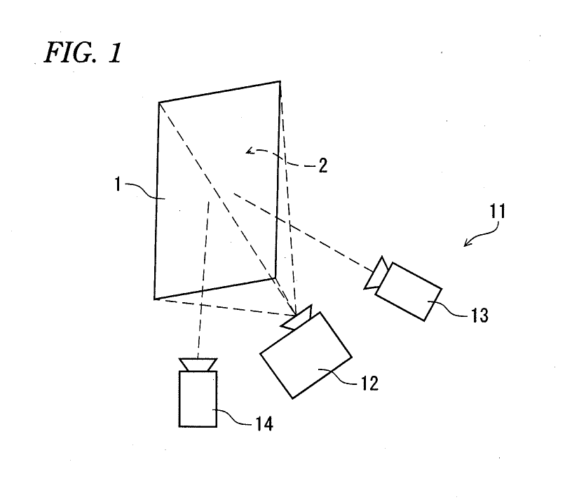

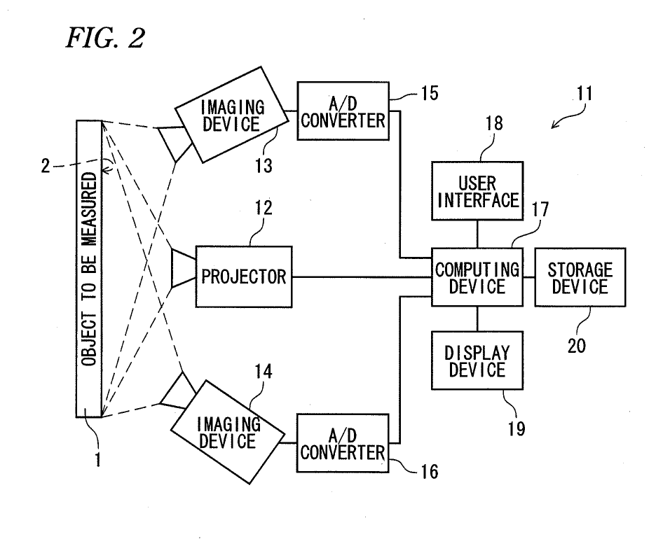

First of all, the configuration of a profile measuring device 11 according to the embodiment will be now described. FIG. 1 illustrates a general configuration of the profile measuring device 11 according to the embodiment. FIG. 2 is a block diagram showing the configuration of the profile measuring device 11. The profile measuring device 11 measures a profile (e.g., a warpage or displacements) of an object 1 to be measured using three-dimensional digital image correlation (3D-DIC) processing. For example, the object 1 is measured in a state that it is set on a stage (not shown).

The profile measuring device 11 includes a projector 12 which projects a speckle pattern 2 using white light (incoherent light). The projector 12 uses white light having many wavelengths, so that projection light is reflected by various constituent members of the object 1.

The projector 12 projects black-and-white pattern as a speckle pattern 2 for image correlation processing. In FIG. 1, the speckle pattern 2 is not drawn as a pattern but as a pattern formation area.

The profile measuring device 11 also includes imaging devices 13 and 14 which capture the object 1 onto which the speckle pattern 2 is projected. In the embodiment, the imaging devices 13 and 14 are CCD (charge-coupled device) cameras. The imaging devices 13 and 14 are disposed such that images of the object 1 are captured at different angles, respectively.

The profile measuring device 11 also includes an A/D converter 15 which converts analog data obtained by the imaging device 13 into digital data, an A/D converter 16 which converts analog data obtained by the imaging device 14 into digital data, and a computing device 17 which receives the digital data from the A/D converters 15 and 16. The imaging devices 13 and 14 may be configured to perform A/D conversion, in a case where the A/D converters 15 and 16 are not provided, respectively.

The profile measuring device 11 further includes: an user interface 18 which receives a user's operation about the profile measuring device 11 (computing device 17), a display device 19 which displays a state of the profile measuring device 11 (computing device 17), and a storage device 20 which stores information generated by the profile measuring device 11 (computing device 17) or the like. In the profile measuring device 11, the computing device 17 is configured to control the individual devices such as the imaging devices 13 and 14 and the projector 12.

The profile measuring device 11 generates 3D data representing the profile of the object 1 by performing image correlation processing with the computing device 17, based on differences (deviations) between images of the object 1 captured by the respective imaging devices 13 and 14 and calculates a warpage, displacements, or the like from the 3D data. The speckle pattern 2 is formed by white light projection instead of coating technique on the surface of the object 1 or diffuse reflection of laser light. Therefore, the profile of the object 1 can be accurately measured without damaging the object 1.

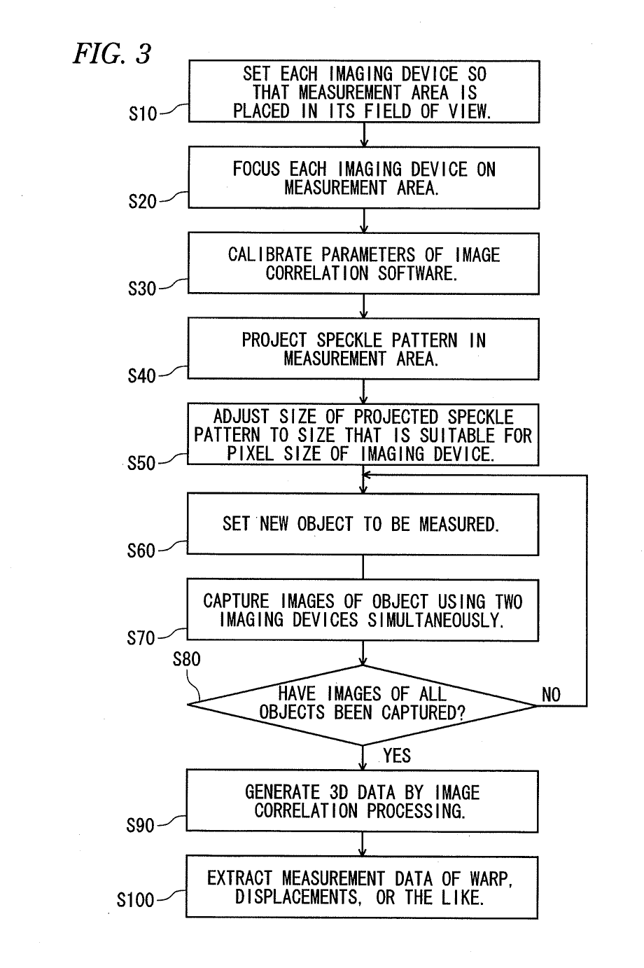

Next, a description will be made of a profile measuring method using the profile measuring device 11 according to the embodiment. FIG. 3 is a flowchart to explain the profile measuring method using the profile measuring device 11.

First, at step S10, a standard sample is set on the stage and each of the imaging devices 13 and 14 (cameras) is set so that a measurement area is placed in its field of view. At step S20, each of the imaging devices 13 and 14 is focused on the measurement area. At step S30, parameters set in image correlation software (program) stored in the storage device 20 in advance are calibrated. At step S40, a speckle pattern 2 is projected onto the standard sample in the measurement area by the projector 12.

At step S50, the size of the projected speckle pattern 2 is adjusted so as to be suitable for the pixel size of the imaging device 13 and 14. In other words, the size of the projected speckle pattern 2 is adjusted to such a size that each of the imaging device 13 and 14 can recognize it.

After execution of steps S10-S50, at step S60 the standard sample is removed and an object to be measured is set on the stage. At step S70, the object 1 is shot by the imaging device 13 and 14 simultaneously.

At step S80, it is determined whether images of all objects to be measured have been captured. If not images of all of the objects have been captured yet (S80: no), the process returns to step S60. On the other hand, if images of all of the objects have been captured (S80: yes), the process moves to step S90. When there remains the next object, the projector 12 may continue emitting white light, because the object 1 is not damaged by the continuous application of white light unlike in the case of using laser light (single-wavelength light). Where the projector 12 is a projector, its light source is in many cases an ultrahigh-pressure mercury lamp (UHE lamp), in which case turning it on again takes long time. Therefore, causing the projector 12 to continue emitting white light can shorten the processing time (in the case where there remains the next object to be measured).

At step S90, the computing device 17 performs image correlation processing on images captured by the imaging devices 13 and 14, whereby 3D data representing a profile of each object 1 is generated. At step S100, measurement data of a warpage, displacements, or the like is extracted from the 3D data.

The profile measuring technique according to the embodiment generates 3D data representing a profile of an object 1 by performing image correlation processing with the computing device 17 based on differences (deviations) between images of the object 1 captured by the respective imaging devices 13 and 14 and calculates a warpage, displacements, or the like from the 3D data. A speckle pattern 2 is formed by white light projection instead of coating on the surface of an object or diffuse reflection of laser light. Therefore, a profile of the object 1 can be measured correctly without damaging the object 1.

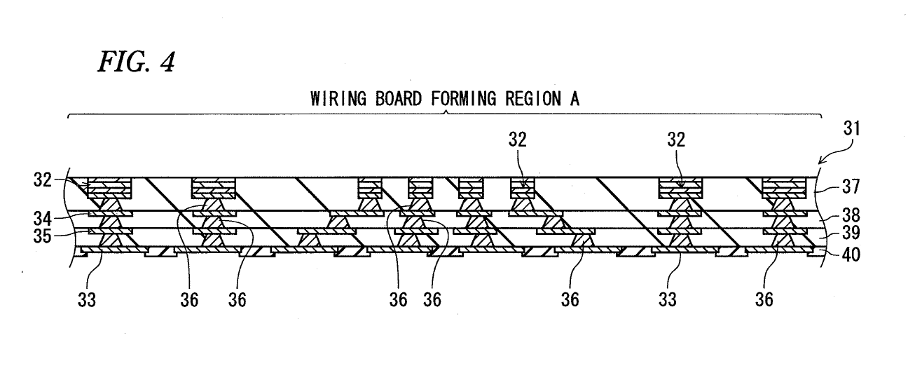

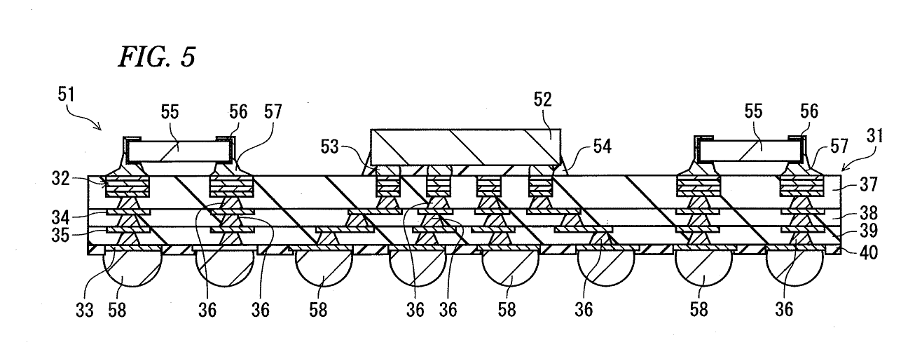

Next, a description will be made of a manufacturing method of semiconductor packages using the profile measuring technique according to the embodiment. FIGS. 4 and 5 are sectional views of a wiring board 31 and a semiconductor package 51, respectively, showing steps of a manufacturing process.

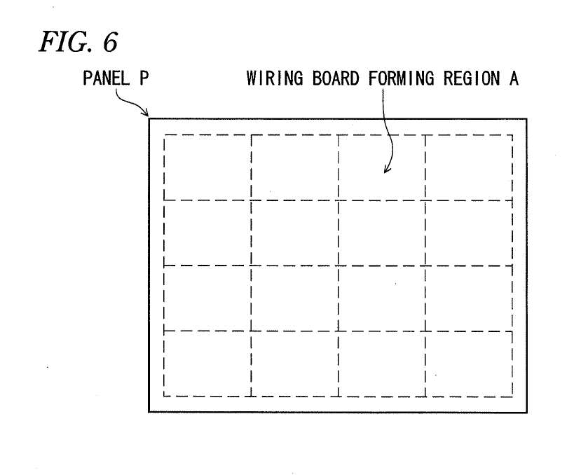

To facilitate understanding of the description, a multiple package production panel P is shown in a plan view of FIG. 6. For example, as shown in FIG. 6, 16 wiring board forming regions A (i.e., regions of individual wiring boards to become semiconductor packages) are formed in the multiple package production panel P which is a single, large-size panel. FIG. 4 is a sectional view of one of the wiring board forming regions of the multiple package production panel P shown in FIG. 6. FIG. 5 is a sectional view of one of semiconductor packages 51 obtained by cutting a multiple package production panel in which semiconductor chips 52 and chip capacitors 55 have been mounted on the multiple package production panel P shown in FIG. 6.

First of all, as shown in FIG. 4, a wiring board 31 is prepared which has metal layers (connection pads 32 etc.) and insulating layers (insulating layer 37 etc.). The wiring board 31 has the chip mounting connection pads 32 on the chip mounting surface (top surface) and solder ball connection pads 33 on the back surface (bottom surface). The wiring board 31 also has wiring patterns 34 and 35 and vias 36 which connect the connection pads 32 and the connection pads 33. The wiring board 31 further includes insulating layers 37, 38, and 39 which electrically insulate the connection pads 32 and 33, the wiring patterns 34 and 35, and the vias 36 from each other. In this manner, the plural insulating layers and the plural wiring layers are formed in the wiring board 31. A solder resist layer 40 having openings through which the connection pads 33 are exposed is formed on the back surface of the wiring board 31

For example, the chip mounting connection pads 32 are formed by plating and consist of four layers, that is, Au, Pd, Ni, and Cu layers arranged in this order from the outside. For example, the solder ball connection pads 33 are formed by plating and are a Cu layer. The wiring patterns 34 and 35 (wiring layers) and the vias 36 are made of Cu, for example. The insulating layers 37, 38, and 39 are epoxy resin layers, for example. The solder resist layer 40 is made of an epoxy resin or a polyester resin, for example. The solder ball connection pads 33 may also consist of Au, Pd, Ni, and Cu layers arranged in this order from the outside.

Then, the profile of the wiring board 31 is measured with the entire wiring board 31 (wiring board forming region) as an object 1 by the above-described profile measuring method. The wiring board 31 (multiple package production panel P) is set on a stage and a speckle pattern 2 is projected onto the chip mounting surface of the wiring board 31 by the projector 12. Then, the size of the speckle pattern 2 is adjusted by the projector 12 to such a size that each of the imaging device 13 and 14 can recognize it.

Then, an image of the chip mounting surface of the wiring board 31 is captured simultaneously by the imaging devices 13 and 14. The profile of the chip mounting surface side of the wiring board 31 is measured by performing image correlation processing on images captured by the respective imaging devices 13 and 14. The profile of the back surface side of the wiring board 31 can also be measured.

For example, the degree of warpage of the wiring board 31 can be checked based on the measured profile of the wiring board 31. If a warpage of an unallowable level is found in the wiring board 31, a countermeasure can be taken such as discard of the wiring board 31 concerned and execution of a process for reducing the warpage. Furthermore, measurement results can be utilized for a warpage survey which is performed before or during a manufacturing process. This makes it possible to avoid mixing of foreign substances at the stage of a manufacturing process.

If a warpage of an unallowable level is not found in the wiring board 31, the wiring board 31 (multiple package production panel P) concerned can be transported to the next manufacturing step as it is. This is because, as described above, in the embodiment, a speckle pattern 2 is formed by white light projection instead of coating on the surface of an object or diffuse reflection of laser light, and hence a warpage or displacements of the wiring board 31 can be measured correctly without damaging the wiring board 31.

A description will now be made of the fact that forming a speckle pattern by white light projection instead of diffuse reflection of laser light (laser speckle method) makes it possible to correctly measure a warpage of a wiring board 31 without damaging the wiring board 31.

In the laser speckle method, a speckle pattern is formed by interference between light beams reflected randomly from the surface of an object being illuminated with single-wavelength laser light (coherent light) and a measurement is performed by capturing the speckle pattern. Therefore, the laser speckle method is effective for a material such as a metal that reflects most of laser light. However, a speckle pattern cannot be projected on a material that does not reflect (i.e., transmits) light having a certain wavelength, such as a semi-transparent material (e.g., insulating layer (resin layer) of a wiring board).

In contrast, since white light contains many wavelength components in a wide range, even a semi-transparent material does not transmit the whole of white light but reflects part of white light to enable capturing of a projected image. The reflectance and the transmittance depend on the wavelength of light, and there should not be such a wavelength that light having that wavelength is reflected by every material used to a large extent without being refracted or absorbed. Therefore, a speckle pattern can be projected when white light (incoherent light) is used in, for example, a projector having an ultrahigh-pressure mercury lamp (UHE lamp), unless an object is a transparent body whose reflectance is close to 0%.

Many insulating materials (including photosensitive ones) used for manufacture of a wiring board are semi-transparent and exhibit low reflectance when laser light (coherent light) is used. It is difficult to recognize the surface of such an insulating material and hence to visualize its profile properly. Therefore, to measure a warpage or displacements or recognize the profile of a wiring board or an in-process large-size panel, a pattern projection technique which uses white light and detects differences in luminance of 256 gradations (white to black), for example.

It is advantageous to project a speckle pattern 2 using white light in measuring the profile of a wiring board 31 whose measurement surface has members made of various materials having various transmittance and reflectance values such as wiring layers (made of metals) and insulating layers (made of resins).

Returning to the description of the manufacturing method, as shown in FIG. 5, a semiconductor chip 52 is then mounted on the chip mounting surface of the wiring board 31. External connection terminals 53 (e.g., solder balls) of the semiconductor chip 52 are electrically connected to the connection pads 32 of the wiring board 31. An underfill resin layer 54 is provided between the semiconductor chip 52 and the wiring board 31 to reduce stress that is caused by the difference between the thermal expansion coefficients of the semiconductor chip 52 and the wiring board 31.

Chip capacitors 55 are mounted on the chip mounting surface of the wiring board 31. External connection terminals 56 of each chip capacitor 55 are electrically connected to connection pads 32 of the wiring board 31 by connection members 57 (e.g., solder), respectively.

Furthermore, solder balls 58 to serve as external connection terminals are provided on the respective connection pads 33 which are formed on the back surface of the wiring board 31. The solder balls 58 are thus electrically connected to the respective connection pads 33 of the wiring board 31. As a result, the solder balls 58 are electrically connected to the semiconductor chip 52 and the chip capacitors 55 via the wiring board 31. A semiconductor package 51 is thus almost completed. The semiconductor package 51 shown in FIG. 5 is an individual one obtained by cutting a large-size panel.

Then, the profile of the semiconductor package 51 is measured with the entire semiconductor package 51 (semiconductor package forming region) as an object 1 by the above-described profile measuring method. The semiconductor package 51 is set on the stage to be kept stationary and a speckle pattern 2 is projected onto the chip mounting surface of the semiconductor package 51 by the projector 12. Then, the size of the speckle pattern 2 is adjusted by the projector 12 to such a size that each of the imaging device 13 and 14 can recognize it.

Then, an image of the chip mounting surface of the semiconductor package 51 is captured simultaneously by the imaging devices 13 and 14. The profile of the chip mounting surface side of the semiconductor package 51 is measured by performing image correlation processing on images captured by the respective imaging device 13 and 14. The profile of the back surface side of the semiconductor package 51 can also be measured.

For example, the degree of warpage of the semiconductor package 51 can be checked from the measured profile of the semiconductor package 51. If a warpage of an unallowable level is found in the semiconductor package 51, a countermeasure can be taken such as discard of the semiconductor package 51 execution of a process for reducing warpage, and a check of the manufacturing process of semiconductor packages 51.

The semiconductor package 51 may be warped due to stress that is caused by the difference between the thermal expansion coefficients of the semiconductor chip 52 (mainly made of silicon) and the wiring board 31 (mainly made of an organic insulating resin). The use of the profile measuring technique is therefore useful. Since as described above a speckle pattern 2 is formed by white light projection instead of coating on the surface of an object or diffuse reflection of laser light, a warpage of the semiconductor package 51 can be measured correctly without damaging the package 51. Reduction in the production yield of the semiconductor package 51 can thus be decreased.

In the case of a POP (package on package) semiconductor package in which another semiconductor chip or package is mounted on the semiconductor package 51, if an electronic component of the semiconductor package 51 is inclined from its regular posture, the other semiconductor chip or package may come into contact with that electronic component when the former is mounted, to cause trouble. Therefore, it is advantageous to measure an inclination of an electronic component mounted on the wiring board 31 using the profile measuring technique according to the embodiment.

For example, the fields of view of the imaging device 13 and 14 are adjusted so that an area around an electronic component is made a measurement area and a speckle pattern 2 is projected in the measurement area by the projector 12. If the size of the speckle pattern 2 is adjusted to such a size that each of the imaging devices 13 and 14 can recognize it, the profile (inclination) of the electronic component can be measured as well as the profile of the entire wiring board 31. In the embodiment, the size of a speckle pattern 2 can be changed easily by adjusting the projector 12 because the speckle pattern 2 is formed by projection.

The profile measuring technique can accommodate a wide range of objects (measurement areas) such as a large-size panel consisting of wiring boards 31, an individual semiconductor package 51, and an electronic component. Furthermore, since a speckle pattern 2 is formed by white light projection instead of coating on the surface of an object or diffuse reflection of laser light, the profile of an object 1 can be measured correctly without damaging the object 1.

In the profile measuring technique, the measurement area can be varied freely. Referring to FIG. 6, examples of the measurement area are the entire area of the multiple package production panel P, a particular wiring board forming region of A of the multiple package production panel P, and only the surface of a semiconductor chip mounted on the multiple package production panel P.

While the present invention has been shown and described with reference to certain exemplary embodiments thereof, other implementations are within the scope of the claims. It will be understood by those skilled in the art that various changes in form and details may be made therein without departing from the spirit and scope of the invention as defined by the appended claims.

For example, although the embodiment has been described in connection with the case that an example object is a wiring board for a semiconductor package, the embodiment can also be applied to a board in a manufacturing process of a wiring board and the surface of a copper-clad lamination board and its in-process board.

The application range of the image correlation technique is broadened because it does not employ coating and is of a non-contact type. Thus, it can be applied to, for example, a sampling inspection or in-line measurement in a manufacturing process of semiconductor packages and a warpage inspection for finished products. More specifically, the speckle size and the speckle pattern projection range can be adjusted or controlled easily. Since a speckle pattern can be projected according to a sample size, measurement can be performed in the same manner on a wiring board, a panel, an individual semiconductor package, and an assembled board (i.e., a board mounted with electronic components).

What is claimed is:

1. A profile measuring device comprising:
a projector which projects a certain pattern on an object to be measured using incoherent light having a plurality of wavelength components;
a first imaging device which captures a first image of the object on which the certain pattern is projected;
a second imaging device which captures a second image of the object on which the certain pattern is projected; and
a computing device which measures a profile of the object based on the first image and the second image.

2. The device of claim 1, wherein the first image and the second image are captured at different angles from each other.

3. The device of claim 1,
wherein the certain pattern is a speckle pattern, and
wherein the incoherent light is white light.

4. The device of claim 2, wherein the computing device generates a 3D image based on the first image and the second image, and measures the profile of the object based on the 3D image.

5. A profile measuring method, comprising:
(a) projecting a certain pattern on an object to be measured using incoherent light having a plurality of wavelength components;
(b) capturing a first image of the object on which the certain pattern is projected;
(c) capturing a second image of the object on which the certain pattern is projected; and
(d) measuring a profile of the object based on the first image and the second image.

6. The method of claim 5, further comprising:
(e) adjusting a size of the certain pattern such that the certain pattern is recognized by first and second imaging devices which capture the first and second images of the object.

7. The method of claim 5,
wherein the certain pattern is a speckle pattern, and
wherein the incoherent light is white light.

8. A method of manufacturing a semiconductor package, comprising:
(a) providing a wiring board for the semiconductor package, comprising wiring layers and insulating layers;
(b) projecting a certain pattern on the wiring board using incoherent light having a plurality of wavelength components;
(c) capturing a first image of the wiring board on which the certain pattern is projected;
(d) capturing a second image of the wiring board on which the certain pattern is projected; and
(e) measuring a profile of the wiring board based on the first image and the second image.

9. A method of manufacturing a semiconductor package, comprising:
(a) providing a wiring board comprising wiring layers and insulating layers;
(b) mounting an electronic component on the wiring board, thereby obtaining a semiconductor package comprising the electronic component and the wiring board;
(c) projecting a certain pattern on the semiconductor package using incoherent light having a plurality of wavelength components;
(d) capturing a first image of the semiconductor package on which the certain pattern is projected;
(e) capturing a second image of the semiconductor package on which the certain pattern is projected; and
(f) measuring a profile of the semiconductor package based on the first image and the second image.
